(19) United States
(12) Patent Application Publication
(10) Pub. No.: US 2025/0299744 A1
(43) Pub. Date: Sep. 25, 2025

(54) PAGE BUFFER RELATED TO A SENSING OPERATION, MEMORY DEVICE INCLUDING A PAGE BUFFER, AND OPERATING METHOD OF A PAGE BUFFER

(71) Applicant: SK hynix Inc., Icheon-si Gyeonggi-do (KR)

(72) Inventor: Kyung Yun JEONG, Icheon-si Gyeonggi-do (KR)

(73) Assignee: SK hynix Inc., Icheon-si Gyeonggi-do (KR)

(21) Appl. No.: 18/942,940

(22) Filed: Nov. 11, 2024

(30) Foreign Application Priority Data
Mar. 20, 2024 (KR) 10-2024-0038369

(51) Int. Cl. G11C 16/26; G11C 16/08; G11C 16/24

(52) U.S. Cl. CPC G11C 16/26; G11C 16/08; G11C 16/24

(57) ABSTRACT

A memory device includes a memory cell array, a page buffer, and a bit line operation controller. The memory cell array includes a memory cell. The page buffer being connected to the memory cell through a bit line. The page buffer configured to perform a sensing operation of sensing program data stored in the memory cell. The bit line operation controller configured to control the page buffer to perform a page buffer under drive operation before the sensing operation. The page buffer including a latch circuit, a sense amp circuit, and a page buffer control switch. The latch circuit configured to store the program data. The sense amp circuit configured to perform the sensing operation. The page buffer control switch configured to connect the bit line and the sense amp circuit to each other.

### CROSS-REFERENCE TO RELATED APPLICATION

The present application claims priority under 35 U.S.C. § 119(a) to Korean patent application number 10-2024-0038369 filed on Mar. 20, 2024, in the Korean Intellectual Property Office, the entire contents of which application is incorporated herein by reference.

### BACKGROUND

### 1. Technical Field

The present disclosure generally relates to an electronic device, and more particularly, to a page buffer related to a sensing operation, a memory device including a page buffer, and an operating method of a page buffer.

### 2. Related Art

A storage device is a device which stores data under the control of a host device such as a computer or a smartphone. The storage device may include a memory device in which data is stored and a memory controller which controls the memory device. The memory device is classified into a volatile memory device and a nonvolatile memory device.

The memory device may include a page buffer which senses data stored in a memory cell. The page buffer may perform a sensing operation by controlling a voltage of a bit line connected to the memory cell. The page buffer adjusts a voltage level of a page buffer control signal, thereby shortening a bit line settling time for setting a bit line voltage to a target level before the sensing operation.

### SUMMARY

In accordance with an embodiment of the present disclosure, there is provided a memory device including: a memory cell array including a memory cell; a page buffer connected to the memory cell through a bit line, the page buffer configured to perform a sensing operation of sensing program data stored in the memory cell; and a bit line operation controller configured to control the page buffer to perform a page buffer under drive operation before the sensing operation, wherein the page buffer includes: a latch circuit configured to store the program data; a sense amplifier (amp) circuit configured to perform the sensing operation; and a page buffer control switch configured to connect the bit line to the sense amp circuit, wherein the page buffer under drive operation is an operation of applying a page buffer control signal having a target voltage level to the page buffer control switch, and wherein the target voltage level is determined based on a read voltage level of a read voltage applied to a word line connected to the memory cell in the sensing operation.

In accordance with an embodiment of the present disclosure, there is provided a page buffer including: a page buffer control switch connected between a bit line connected to a memory cell and a common sensing node, the page buffer control switch configured to be controlled according to a page buffer control signal; first and second switches connected in series between a power node and a sensing node; a third switch connected between the sensing node and the common sensing node, the third switch configured to be controlled according to a sense amplifier (amp) sensing signal; fourth and fifth switches connected in series between the sensing node and a ground node; and a latch circuit configured to store data sensed from the memory cell, wherein the first switch and the fifth switch are controlled according to the data stored in the latch circuit, the second switch is controlled according to a sense amp precharge signal, and the fourth switch is controlled according to a sense amp discharge signal, wherein the page buffer control signal having a target voltage level is applied to the page buffer control switch before a sensing operation on the memory cell, and wherein the target voltage level is determined according to a read voltage level of a read voltage applied to a word line connected to the memory cell in the sensing operation.

In accordance with an embodiment of the present disclosure, there is provided a method of operating a memory device, the method including: performing a page buffer under drive operation before a sensing operation of sensing data stored in a memory cell, and performing the sensing operation by applying a read voltage to a word line connected to the memory cell. In an embodiment, the performing of the page buffer under drive operation includes: determining a target voltage level of a page buffer control signal, based on a read voltage level of the read voltage, and applying the page buffer control signal having the target voltage level to a page buffer control switch connecting a bit line connected to the memory cell to a latch circuit storing the data.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like reference numerals refer to like elements throughout.

FIG. 1 is a diagram illustrating a memory device in accordance with an embodiment of the present disclosure.

FIG. 2 is a diagram illustrating a page buffer in accordance with an embodiment of the present disclosure.

FIG. 3 is a diagram illustrating a bit line shielding operation in accordance with an embodiment of the present disclosure.

FIG. 4 is a timing diagram illustrating a first sensing operation in accordance with an embodiment of the present disclosure.

FIG. 5A is a timing diagram illustrating a second sensing operation in accordance with an embodiment of the present disclosure.

FIG. 5B is a timing diagram illustrating a second sensing operation in accordance with an embodiment of the present disclosure.

FIG. 6 is a diagram illustrating a bit line settling time in a sensing operation in accordance with an embodiment of the present disclosure.

FIG. 7 is a diagram illustrating a bit line settling time in a sensing operation in accordance with an embodiment of the present disclosure.

FIG. 8A is a diagram illustrating a probability that a memory cell will be read as a program cell according to a read level in accordance with an embodiment of the present disclosure.

FIG. 8B is a diagram illustrating a probability that a memory cell will be read as a program cell according to a read level in accordance with an embodiment of the present disclosure.

FIG. 9 is a diagram illustrating a probability that a memory cell will be read as a program cell in the first sensing operation in accordance with an embodiment of the present disclosure.

FIG. 10 is a diagram illustrating a probability that a memory cell will be read as a program cell in the second sensing operation in accordance with an embodiment of the present disclosure.

FIG. 11 is a diagram illustrating setting operation on a page buffer control signal in accordance with an embodiment of the present disclosure.

FIG. 12 is a diagram illustrating a page buffer under drive operation and a sensing operation in accordance with an embodiment of the present disclosure.

FIG. 13 is a flowchart illustrating an operation of the memory device in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Various embodiments provide a page buffer, a memory device including a page buffer, and an operating method of a page buffer, in which a voltage level of a page buffer control signal is adjusted before a sensing operation, thereby shortening a bit line settling time and performing the sensing operation.

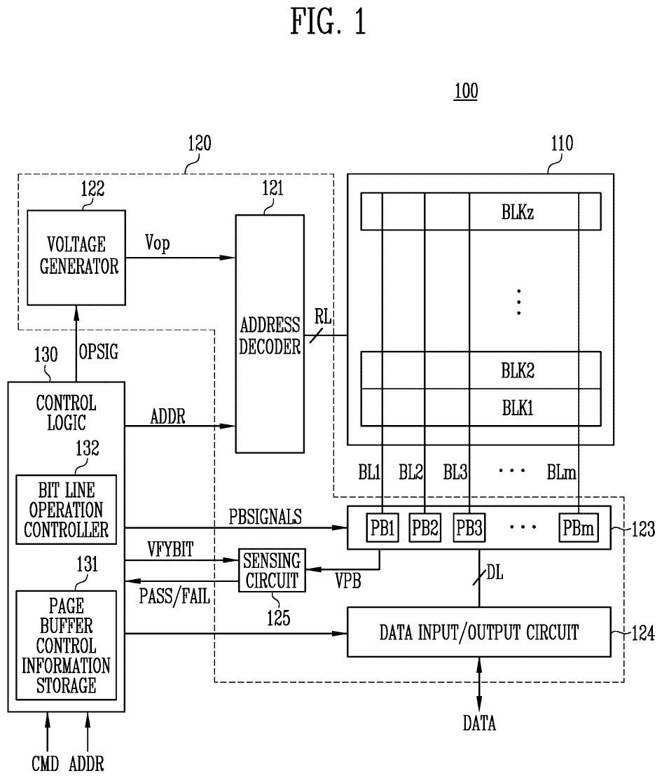

FIG. 1 is a diagram illustrating a memory device in accordance with an embodiment of the present disclosure.

Referring to FIG. 1, the memory device 100 may include a memory cell array 110, a peripheral circuit 120, and control logic 130. The control logic 130 may be implemented as hardware, software, or a combination of hardware and software. For example, the control logic 130 may be a control logic circuit operating in accordance with an algorithm and/or a processor executing control logic code.

The memory cell array 110 may include a plurality of memory blocks BLK1 to BLKz. The plurality of memory blocks BLK1 to BLKz may be connected to an address decoder 121 through row lines RL. The plurality of memory blocks BLK1 to BLKz may be connected to a read/write circuit 123 through bit lines BL1 to BLm. Each of the plurality of memory blocks BLK1 to BLKz may include a plurality of memory cells. In an embodiment, the plurality of memory cells may be nonvolatile memory cells.

Each of the memory cells of the memory device 100 may be configured as a Single Level Cell (SLC) storing one-bit data, a Multi-Level Cell (MLC) storing two-bit data, a Triple Level Cell (TLC) storing three-bit data, or a Quad Level Cell (QLC) storing four-bit data.

The peripheral circuit 120 may include the address decoder 121, a voltage generator 122, the read/write circuit 123, a data input/output circuit 124, and a sensing circuit 125.

The peripheral circuit 120 may drive the memory cell array 110. For example, the peripheral circuit 120 may drive the memory cell array 110 to perform a program operation, a read operation, and an erase operation.

The address decoder 121 may be connected to the memory cell array 110 through the row lines RL. The row lines RL may include drain select lines, word lines, source select lines, and a common source line.

The address decoder 121 may operate under the control of the control logic 130. The address decoder 121 may receive an address ADDR from the control logic 130.

The address decoder 121 may decode a block address in the received address ADDR. The address decoder 121 may select at least one memory block among the memory blocks BLK1 to BLKz according to the decoded block address. The address decoder 121 may decode a row address in the received address ADDR. The address decoder 121 may select at least one word line among word lines of the selected memory block according to decoded row address. The address decoder 121 may apply an operating voltage Vop supplied from the voltage generator 122 to the selected word line.

In a program operation, the address decoder 121 may apply a program voltage to the selected word line, and apply a pass voltage having a level lower than a level of the program voltage to unselected word lines. In a program verify operation, the address decoder 121 may apply a verify voltage to the selected word line, and apply a verify pass voltage having a level higher than a level of the verify voltage to the unselected word lines. In a read operation, the address decoder 121 may apply a read voltage to the selected word line, and apply a read pass voltage having a level higher than a level of the read voltage to the unselected word lines. In an erase operation, the address decoder 121 may apply a ground voltage to the word lines of the selected memory block.

In accordance with an embodiment of the present disclosure, an erase operation of the memory device 100 may be performed in units of memory blocks. An address ADDR input to the memory device 100 in the erase operation may include a block address.

In accordance with an embodiment of the present disclosure, the address decoder 121 may decode a column address in the received address ADDR. The decoded column address may be transferred to the read/write circuit 123. For example, the address decoder 121 may include components such as a row decoder, a column decoder, and an address buffer.

The voltage generator 122 may generate a plurality of operating voltages Vop by using an external power voltage supplied to the memory device 100. The voltage generator 122 may operate under the control of the control logic 130.

In an embodiment, the voltage generator 122 may generate an internal power voltage by regulating the external power voltage. The internal power voltage generated by the voltage generator 122 may be used as an operating voltage of the memory device 100.

In an embodiment, the voltage generator 122 may generate a plurality of operating voltages Vop by using the external power voltage or the internal power voltage. The voltage generator 122 may generate various voltages required in the memory device 100. For example, the voltage generator 122 may generate a plurality of erase voltages, a plurality of program voltages, a plurality of pass voltages, a plurality of select read voltages, and a plurality of unselect read voltages.

In order to generate a plurality of operating voltages Vop having various voltage levels, the voltage generator 122 may include a plurality of camping capacitors which receive the internal power voltage. The voltage generator 122 may generate the plurality of operating voltages Vop by selectively enabling the plurality of pumping capacitors under the control of the control logic 150. The plurality of operating voltages generated by the voltage generator 122 may be supplied to the memory cell array 110 by the address decoder 121.

The read/write circuit 123 may include first to mth page buffers PB1 to PBm. The first to mth page buffers PB1 to PBm may be connected to the memory cell array 110 respectively through first to mth bit lines BL1 to BLm. The first to mth page buffers PB1 to PBm may operate under the control of the control logic 130.

The first to mth page buffers PB1 to PBm may communicate data DATA with the data input/output circuit 124. In a program operation, the first to mth page buffers PB1 to PBm may receive data DATA to be stored through the data input/output circuit 124 and data lines DL.

In a program operation, the first to mth page buffers PB1 to PBm may transfer data DATA received through the data input/output circuit 124 to selected memory cells through the bit lines BL1 to BLm when a program voltage is applied to the selected word line. Memory cells of a selected page may be programmed according to the transferred data DATA. A threshold voltage of a memory cell connected to a bit line through which a program allow voltage (e.g., a ground voltage) is applied may increase. A threshold voltage of a memory cell connected to a bit line through which a program inhibit voltage (e.g., a power voltage) is applied may be maintained. In a program verify operation, the first to mth page buffers PB1 to PBm may read data DATA stored in the selected memory cells from the memory cells through the bit lines BL1 to BLm.

In an embodiment, the first to mth page buffers PB1 to PBm may be connected to the selected memory cells through the bit lines BL1 to BLm, and perform a sensing operation of sensing program data stored in the selected memory cells. Each page buffer may include a latch circuit which stores the program data, a sense amplifier (amp) circuit which performs the sensing operation, and a page buffer control switch which connects a bit line and the sense amp circuit to each other.

In a read operation, the read/write circuit 123 may read data DATA from memory cells of a selected page through the bit lines BL1 to BLm, and store the read data DATA in the first to mth page buffers PB1 to PBm.

In an erase operation, the read/write circuit 123 may float the bit lines BL. In an embodiment, the read/write circuit 123 may include a column select circuit.

The data input/output circuit 124 may be connected to the first to mth page buffers PB1 to PBm through the data lines DL. The data input/output circuit 124 may operate under the control of the control logic 130.

The data input/output circuit 124 may include a plurality of input/output buffers (not shown) which receive input data DATA. In a program operation, the data input/output circuit 124 may receive data DATA to be stored from an external controller (not shown). In a read operation, the data input/output circuit 124 may output, to the external controller, data DATA transferred from the first to mth page buffers PB1 to PBm included in the read/write circuit 123.

In a read operation or verify operation, the sensing circuit 125 may generate a reference current in response to an allow bit VRYBIT generated by the control logic 130, and output a pass or fail signal PASS/FAIL to the control logic 130 by comparing a sensing voltage VPB received from the read/write circuit 123 with a reference voltage generated by the reference current.

The control logic 130 may be connected to the address decoder 121, the voltage generator 122, the read/write circuit 123, the data input/output circuit 124, and the sensing circuit 125. The control logic 130 may control a general operation of the memory device 100. The control logic 130 may operate in response to a command CMD transferred from an external device.

The control logic 130 may control the peripheral circuit 120 by generating several signals in response to a command CMD and an address ADDR. For example, the control logic 130 may generate the operation signal OPSIG, the address ADDR, a read/write circuit control signal PBSIGNALS, and the allow bit VRYBIT in response to the command CMD and the address ADDR. The control logic 130 may output the operation signal OPSIG to the voltage generator 122, output the address ADDR to the address decoder 121, output the read/write circuit control signal PBSIGNALS to the read/write circuit 123, and output the allow bit VRYBIT to the sensing circuit 125. Also, the control logic 130 may determine whether the verify operation has passed or failed in response to the pass or fail signal PASS/FAIL output by the sensing circuit 125.

The control logic 130 may include a page buffer control information storage 131 and a bit line operation controller 132. In an embodiment, the page buffer control information storage 131 may be implemented as hardware, software, or a combination of hardware and software. For example, the page buffer control information storage 131 may be a page buffer control information storage circuit operating in accordance with an algorithm and/or a processor executing page buffer control information storage code. In an embodiment, the bit line operation controller 132 may be implemented as hardware, software, or a combination of hardware and software. For example, the bit line operation controller 132 may be a bit line operation controller circuit operating in accordance with an algorithm and/or a processor executing bit line operation controller code.

The page buffer control information storage 131 may store setting information on a page buffer control signal. The setting information may include an offset voltage level of the page buffer control signal, which corresponds to a read voltage level of a read voltage applied to a word line connected to a selected memory cell. The setting information may include a probability that a memory cell connected to a bit line adjacent to a bit line connected to the selected memory cell will be read as a program cell by the read voltage level. The setting information may include an under drive group to which the read voltage level belongs according to the offset voltage level. The magnitude of the offset voltage level may be in inverse proportion to the probability that the memory cell will be read as the program cell.

The bit line operation controller 132 may control a page buffer to perform a page buffer under drive operation before a sensing operation. The page buffer under drive operation may be an operation of applying a page buffer control signal having a target voltage level to a page buffer control switch. The target voltage level may be determined based on a read voltage level of a read voltage applied to a word line connected to a selected memory cell in the sensing operation. For example, the target voltage level may be determined based on a default voltage level and an offset voltage level of the page buffer control signal.

The bit line operation controller 132 may determine a target voltage level, based on the setting information, and control the page buffer to perform the page buffer under drive operation while a word line under drive operation is performed on the word line. The bit line operation controller 132 may terminate the page buffer under drive operation before a word line settling operation of setting a potential of the word line to the read voltage level is completed. The word line under drive operation may be an operation of applying, to the word line, an under drive voltage having a level lower than the read voltage level before the sensing operation.

The bit line operation controller 132 may control the page buffer to perform a next sensing operation by changing the read voltage level after the sensing operation is performed. The page buffer may disable a sense amp circuit in the subsequent next sensing operation according to a result of the sensing operation. The page buffer may apply a shielding voltage to a bit line in the subsequent next sensing operation.

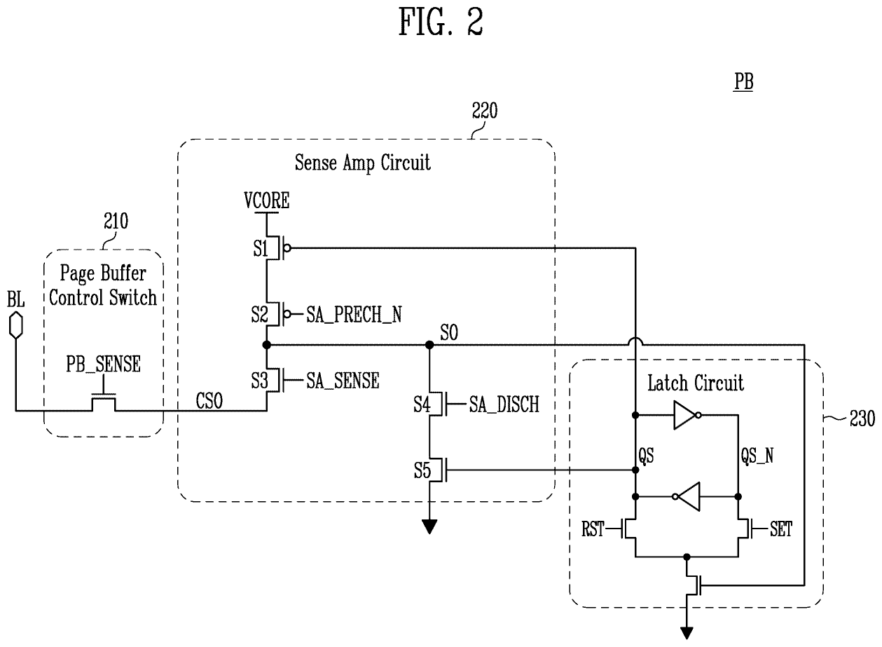

FIG. 2 is a diagram illustrating a page buffer in accordance with an embodiment of the present disclosure.

Referring to FIG. 2, the page buffer PB may include a page buffer control switch 210, a sense amplifier (amp) circuit 220, and a latch circuit 230. The page buffer control switch 210 may connect a bit line BL and the sense amp circuit 220 to each other. The sense amp circuit 220 may perform a sensing operation of sensing program data stored in a memory cell connected to the bit line BL. The latch circuit 230 may store the program data sensed by the sense amp circuit 220.

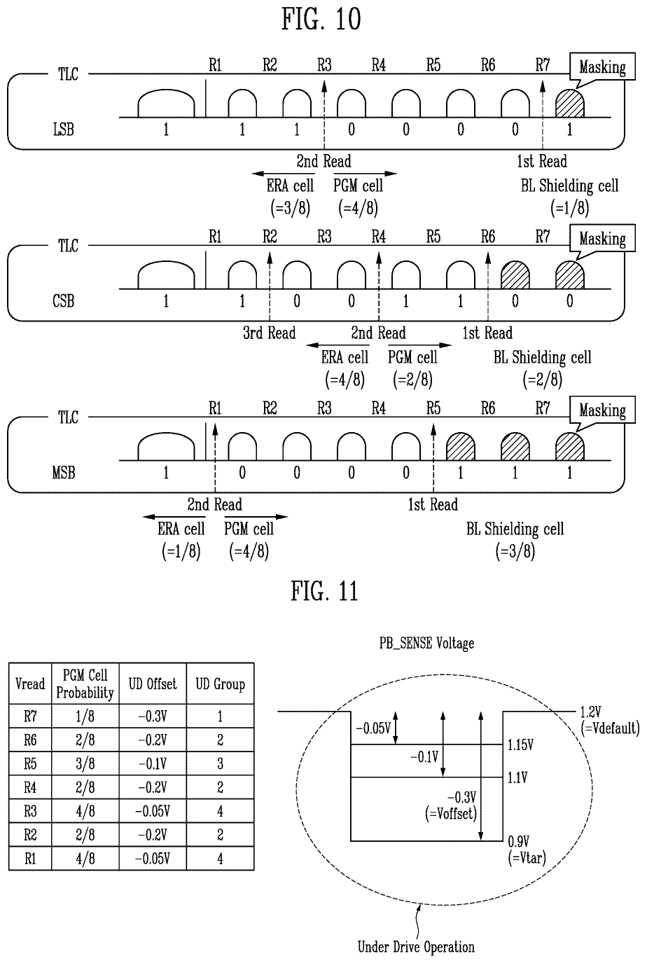

In FIG. 2, the page buffer control switch 210 may be connected between the bit line BL connected to the memory cell and a common sensing node CSO, and be controlled according to a page buffer control signal PB_SENSE. A page buffer under drive operation may be an operation of applying the page buffer control signal PB_SENSE having a target voltage level to the page buffer control switch 210 before the sensing operation. The target voltage level may be determined based on a read voltage level of a read voltage applied to a word line connected to the memory cell in the sensing operation as will be described in FIG. 11. The page buffer control signal PB_SENSE may maintain the target voltage level while an under drive voltage having a level lower than the read voltage level is applied to the word line. The page buffer control signal PB_SENSE may be changed from the target voltage level to a default voltage level before a potential of the word line reaches the read voltage level.

The sense amp circuit 220 may include first to fifth switches S1 to S5.

The first and second switches S1 and S2 may be connected in series between a power node VCORE and a sensing node SO. The first switch S1 may be controlled according to the program data stored in the latch circuit 230. The second switch S2 may be controlled according to a sense amp precharge signal SA_PRECH_N. The third switch S3 may be connected to the sensing node SO and the common sensing node CSO, and be controlled according to a sense amp sensing signal SA_SENSE. The fourth and fifth switches S4 and S5 may be connected in series between the sensing node SO and a ground node. The fourth switch S4 may be controlled according to a sense amp discharge signal SA_DISCH. The sense amp discharge signal SA_DISCH may be inactivated in a first sensing operation as an initial sensing operation, and be activated in a second sensing operation as a subsequent next sensing operation. The fifth switch S5 may be controlled according to the program data stored in the latch circuit 230.

In an embodiment, as the sense amp discharge signal SA_DISCH is always activated in the next sensing operation except the initial sensing operation, the sense amp circuit 220 may be enabled or disabled according to a result of a previous sensing operation, which is stored in the latch circuit 230. For example, when a data value stored in the latch circuit 230 is 1, a potential of the sensing node SO may be discharged to a ground level, and the sense amp circuit 220 may be disabled. When the data voltage stored in the latch circuit 230 is 0, the potential of the sense node SO is not discharged to the ground level, and therefore, the sense amp circuit 220 may be enabled. The enabled sense amp circuit 220 may normally perform the sensing operation.

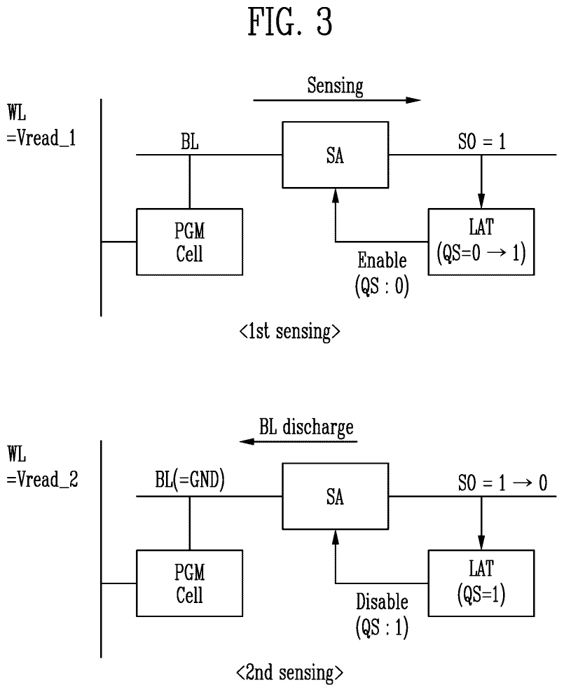

FIG. 3 is a diagram illustrating a bit line shielding operation in accordance with an embodiment of the present disclosure.

Referring to FIG. 3, before a first sensing operation (i.e., <1st sensing>), data of a latch circuit LAT may be initialized to 0, and data of a sensing node SO may be initialized to 1. Vread_1 may be applied as a read voltage to a word line connected to a memory cell. A sense amp circuit SA may be enabled or disabled according to data QS of the latch circuit LAT. For example, when the data QS of the latch circuit LAT is 0, the sense amp circuit SA may be enabled. When the data QS of the latch circuit LAT is 1, the sense amp circuit SA may be disabled. The sense amp circuit SA may reflect data sensed from the memory cell on the sensing node SO. For example, when the memory cell is read as an erase cell by Vread_1 as the read voltage, the data of the sensing node SO may be set to 0. When the memory cell is read as a program cell, the data of the sensing node SO may be set to 1. When the data of the sensing node SO is 0, the data QS of the latch circuit LAT may maintain a current value. When the data of the sensing node SO is 1, the data QS of the latch circuit LAT may be set to 1.

In FIG. 3, because the memory cell is read as the program cell by Vread_1 as the read voltage in the first sensing operation, the data of the sensing node SO may be set to 1, and the data QS of the latch circuit LAT may be set to 1.

Before a second sensing operation (i.e., <2nd sensing>), the data of the sensing node SO may be initialized to 1. The latch circuit LAT may store, as data, 1 as a result of the first sensing operation. Vread_2 may be applied as a read voltage to the word line connected to the memory cell. Because the data QS of the latch circuit LAT is 1, the sense amp circuit SA may be disabled. While the sense amp circuit SA is disabled, a bit line shielding operation of applying a shielding voltage to a bit line BL may be performed. The shielding voltage may include a ground voltage GND. In other words, the shielding voltage may be applied to the bit line BL according to the result of the first sensing operation in the second sensing operation in which a read voltage level is changed from Vread_1 to Vread_2.

In another embodiment, when the memory cell is read as the erase cell by Vread_1 as the read voltage in the first sensing operation, the data of the sensing node SO may be set to 0, and the data QS of the latch circuit LAT may be set to 0. Before the second sensing operation, the data of the sensing node SO may be initialized to 1. The latch circuit LAT may store, as data, 0 as a result of the sensing operation. Vread_2 may be applied as the read voltage to the word line connected to the memory cell. Because the data QS of the latch circuit LAT is 0, the sense amp circuit SA may be enabled. The sense amp circuit SA may perform the second sensing operation, like the first sensing operation.

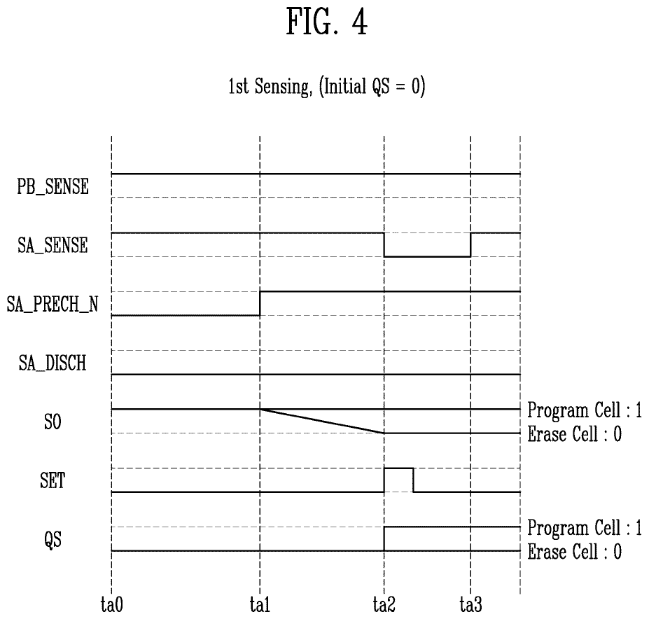

FIG. 4 is a timing diagram illustrating a first sensing operation (i.e., 1st Sensing) in accordance with an embodiment of the present disclosure.

Referring to FIG. 4, ta0 (i.e., time point ta0), the page buffer control signal PB_SENSE, the sense amp sensing signal SA_SENSE, and the sense amp precharge signal SA_PRECH_N may be in an activation state. The sense amp discharge signal SA_DISCH may be in an inactivation state. The data of the sensing node SO may be set to 1. A set signal SET of a latch circuit may be in the inactivation state. The data QS of the latch circuit may be initially set to 0. Referring to FIG. 2, at ta0, the first and second switches S1 and S2 are activated. Therefore, the sensing node SO may be precharged to a power voltage level, and the data may be set to 1.

At ta1, the sense amp precharge signal SA_PRECH_N may be changed from the activation state to the inactivation state. Accordingly, the potential of the sensing node SO may follow a potential of the bit line BL.

At ta1 to ta2, when the memory cell connected to the bit line BL is read as a program cell, the potential of the sensing node SO may be maintained, and the data may be set to 1. When the memory cell connected to the bit line BL is read as an erase cell, the potential of the sensing node SO may be discharged, and the data may be set to 0.

At ta2, the sense amp sensing signal SA_SENSE may be changed from the activation state to the inactivation state. The set signal SET of the latch circuit may be changed from the inactivation state to the activation state. As the set signal SET of the latch circuit is activated, the data of the sensing node SO may be stored as the data QS of the latch circuit.

At ta3, the sense amp sensing signal SA_SENSE may be changed from the inactivation state to the activation state.

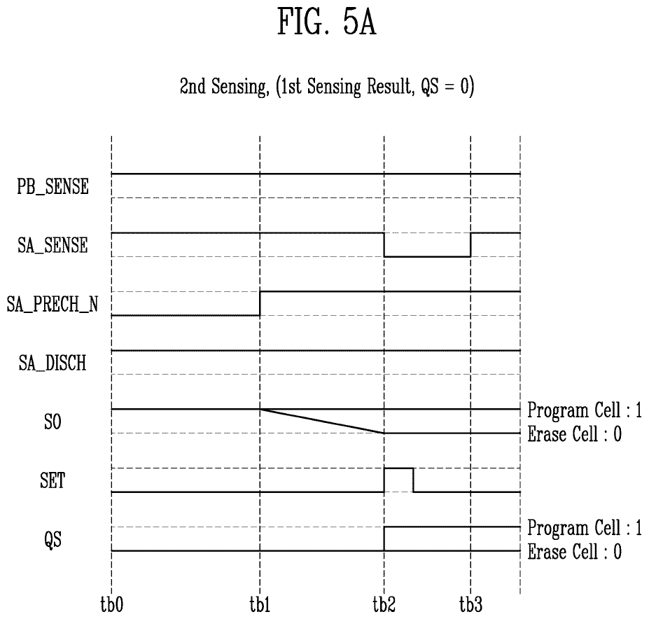

FIG. 5A is a timing diagram illustrating a second sensing operation (i.e., 2nd Sensing) in accordance with an embodiment of the present disclosure.

Referring to FIG. 5A, at tb0 (i.e., time point tb0), the page buffer control signal PB_SENSE, the sense amp sensing signal SA_SENSE, the sense amp precharge signal SA_PRECH_N, and the sense amp discharge signal SA_DISCH may be in the activation state. In the case of a second sensing operation, the sense amp discharge signal SA_DISCH may be continuously in the activation state, unlike the first sensing operation described with reference to FIG. 4. The data of the sensing node SO may be set to 1. The set signal SET of the latch circuit may be in the inactivation state. The data QS of the latch circuit may be set to a result of the first sensing operation. In the case of FIG. 5A, as the memory cell is read an erase cell, the data QS of the latch circuit may be set to 0.

When the memory cell is read as an erase cell in the first sensing operation, the second sensing operation may be performed identically to the first sensing operation described with reference to FIG. 4, except that the sense amp discharge signal SA_DISCH is in the activation state.

FIG. 5B is a timing diagram illustrating a second sensing operation in accordance with an embodiment of the present disclosure.

Referring to FIG. 5B, at tc0 (i.e., time point tc0), the page buffer control signal PB_SENSE, the sense amp sensing signal SA_SENSE, the sense amp precharge signal SA_PRECH_N, and the sense amp discharge signal SA_DISCH may be in the activation state. In the case of a second sensing operation, the sense amp discharge signal SA_DISCH may be continuously in the activation state, unlike the first sensing operation described with reference to FIG. 4. The set signal SET of the latch circuit may be in the inactivation state. The data QS of the latch circuit may be set to a result of the first sensing operation. In the case of FIG. 5B, as the memory cell is read as a program cell in the first sensing operation, the data QS of the latch circuit may be set to 1.

Referring to FIG. 2, the sense amp discharge signal SA_DISCH is in the activation state, and the data QS of the latch circuit is 1. Therefore, both the fourth and fifth switches S4 and S5 may be activated, and the sensing node SO may be connected to the ground node. Accordingly, the potential of the sensing node SO may be discharged to a ground voltage level, and the data of the sensing node SO may be set to 0.

Because the sensing node SO is electrically connected to the bit line BL while the sense amp sensing signal SA_SENSE is in the activation state, the potential of the bit line BL may also be discharged to the ground voltage level, and a bit line shielding operation may be performed.

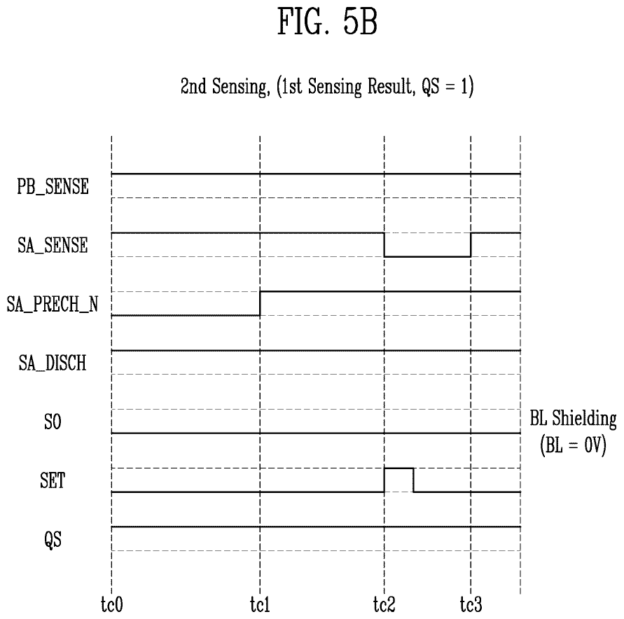

FIG. 6 is a diagram illustrating a bit line settling time in a sensing operation in accordance with an embodiment of the present disclosure.

Referring to FIG. 6, when a read voltage Vread applied to a word line is higher than a threshold voltage Vt of a memory cell (i.e., Cell Vt) in a sensing operation, waveforms of a word line potential, a bit line potential, a cell current, and a sensing current are illustrated. Because the read voltage Vread is higher than the threshold voltage Vt of the memory cell Cell, the memory cell may be read as an erase cell.

In order to shorten a word line settling time for setting a potential of the word line to a read voltage level, an under drive voltage may be applied to the word line. Therefore, an undershoot in which the cell current excessively falls may occur, and an undershoot may also occur in the sensing current following the cell current. A bit line settling time for setting a potential of a bit line to a target level may be increased due to the undershoot of the sensing current.

In Case 1, a page buffer under drive operation PB UD of applying, to a page buffer control switch, a page buffer control signal having a target voltage level lower than a default voltage level might not be performed. Bit line settling may be completed at a time c1.

In Case 2, the page buffer under drive operation PB UD may be performed. The page buffer under drive operation PB UD may be terminated before word line settling is completed. When the page buffer under drive operation PB UD is terminated, the page buffer control signal may be returned from the target voltage level to the default voltage level. Therefore, a gate voltage of the page buffer control switch may temporarily suddenly rise, and an overshoot may be forcibly caused in the cell current. The cell current may be released in an undershoot state due to the overshoot, and the bit line settling may be terminated at a time c2.

In the embodiment described with reference to FIG. 6, when the memory cell is read as an erase cell, a time at which the bit line settling is terminated may be shortened by tp1 from c1 to c2 when the page buffer under drive operation PB UD is performed.

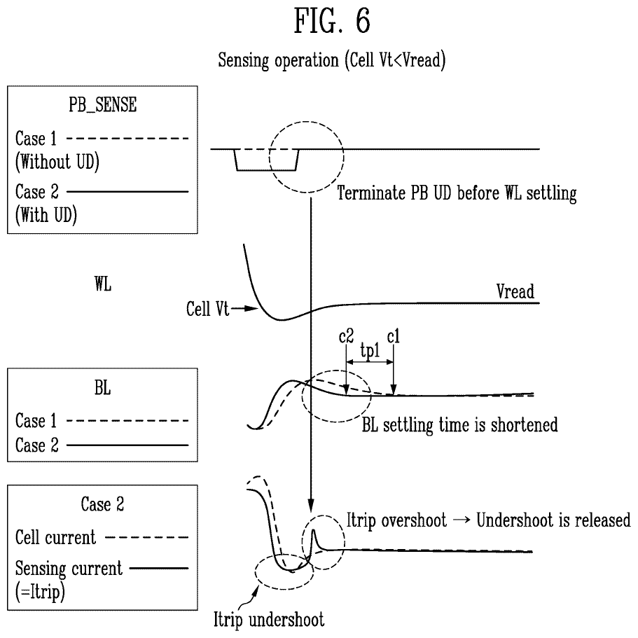

FIG. 7 is a diagram illustrating a bit line settling time in a sensing operation in accordance with an embodiment of the present disclosure.

Referring to FIG. 7, when a read voltage Vread applied to a word line is lower than a threshold voltage Vt of a memory cell in a sensing operation, waveforms of a word line potential, a bit line potential, a cell current, and a sensing current are illustrated. Because the read voltage Vread is lower than the threshold voltage Vt of the memory cell, the memory cell may be read as a program cell.

In order to shorten a word line settling time for setting a potential of the word line to a read voltage level, an under drive voltage may be applied to the word line. Because the read voltage Vread is lower than the threshold voltage Vt of the memory cell, the cell current (−0 nA) and the sensing current (−4 nA) have very small values and hardly have influence on a read result.

On the other hand, when a page buffer under drive operation PB UD is performed, a potential of a bit line follows a voltage of a page buffer control switch, and therefore, bit line voltage rising may be suppressed in a state in which a bit line voltage is low. As the bit line voltage rising is delayed, noise may be caused in an adjacent bit line through a parasitic capacitor for a longer time, and a bit line settling time may be degraded.

In the embodiment described with reference to FIG. 7, when the memory cell is read as the program cell, a time at which the bit line settling time is terminated may be delayed by tp2 from d1 to d2 when the page buffer under drive operation PB UD is performed. That is, when the memory cell is read as the program cell, an excessive page buffer under drive operation may disrupt the bit line settling, and the bit line settling time may be increased.

Thus, according to a probability that as a memory cell connected to an adjacent bit line will be read as a program cell as will be described later in FIG. 11, the intensity of the page buffer under drive operation is adjusted, so that, in an embodiment, the bit line settling time can be optimally shortened.

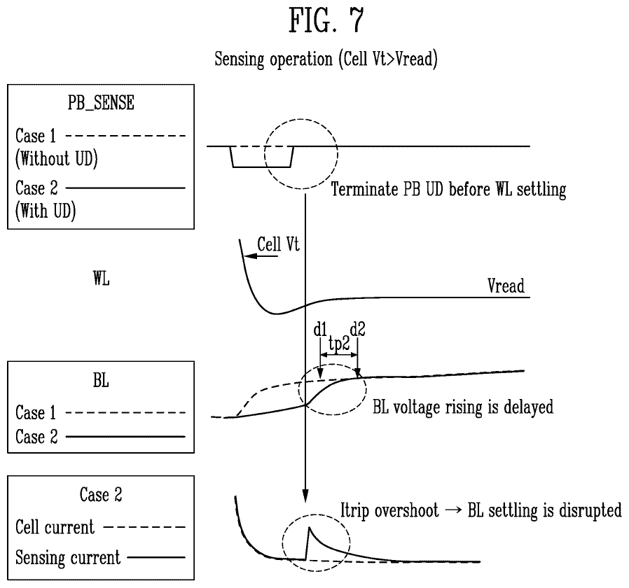

FIG. 8A is a diagram illustrating a probability that a memory cell will be read as a program cell according to a read level in accordance with an embodiment of the present disclosure.

Referring to FIG. 8A, it is assumed that a memory cell is a triple level cell storing three data bits. The number of data bits stored by the memory cell is not limited to this embodiment.

A threshold voltage distribution of the memory cell may be divided by first to seventh read levels R1 to R7. When Least Significant Bit (LSB) data stored in the memory cell is read, a first sensing operation (e.g., 1st Read) is performed according to the seventh read level R7, and a second sensing operation (e.g., 2nd Read) may be performed according to the third read level R3. The probability that the memory cell will be read as a program cell (e.g., PGM cell) in the first sensing operation may be 1/8. The probability that the memory cell will be read as an erased cell (e.g., ERA cell) in the first sensing operation may be 7/8. The probability that the memory cell will be read as the program cell in the second sensing operation may be 5/8. The probability that the memory cell will be read as the erased cell in the second sensing operation may be 3/8.

FIG. 8B is a diagram illustrating a probability that a memory cell will be read as a program cell according to a read level in accordance with an embodiment of the present disclosure.

Referring to FIG. 8B, like as described in FIG. 8A, a Least Significant Bit (LSB) data may be read to the memory cell. However, as described with reference to FIGS. 3 and 5B, when the memory cell is read as a program cell in a sensing operation, a bit line shielding operation of applying a shielding voltage to a bit line connected to the corresponding memory cell in a subsequent next sensing operation may be performed.

Therefore, the first sensing operation may be performed according to the seventh read level R7, the memory cell read as the program cell may be masked by the seventh read level, and the bit line shielding operation may be performed. The masked memory cell may be read as a bit line shielding cell instead of the program cell in the next sensing operation.

Therefore, except the masked memory cell, the probability that the memory cell will be read as the program cell according to the third read level R3 in the second sensing operation may be 4/8.

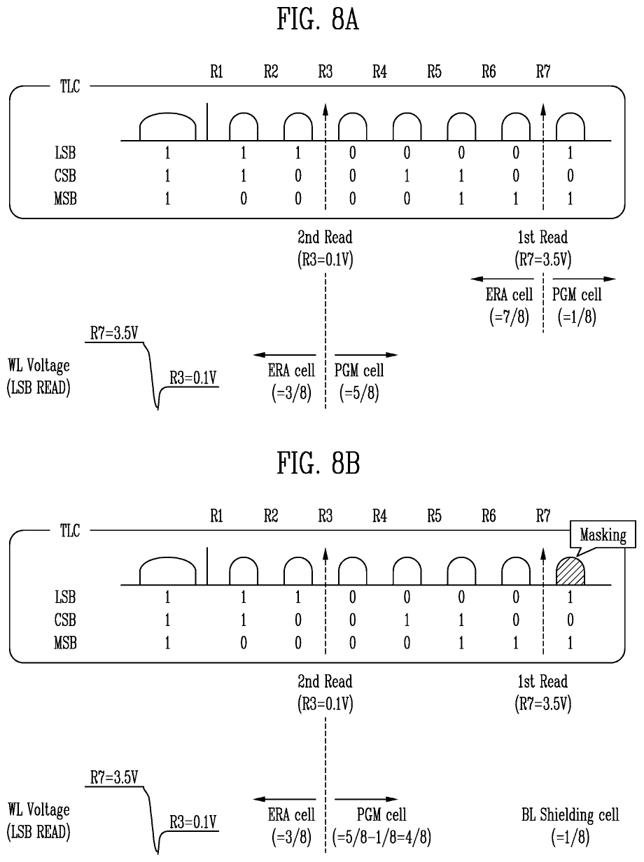

FIG. 9 is a diagram illustrating a probability that a memory cell will be read as a program cell in the first sensing operation in accordance with an embodiment of the present disclosure.

Referring to FIG. 9, in the case of the first sensing operation as an initial sensing operation, no bit line shielding cell exists in memory cell reading. Therefore, in the case of the first sensing operation of sensing Least Significant Bit (LSB) data stored in the memory cell according to the seventh read level R7, the probability that the memory cell will be read as a program cell may be 1/8. In the case of the first sensing operation of sensing Central Significant Bit (CSB) data stored in the memory cell according to the sixth read level R6, the probability that the memory cell will be read as the program cell may be 2/8. In the case of the first sensing operation of sensing Most Significant Bit (MSB) data stored in the memory cell according to the fifth read level R5, the probability that the memory cell will be read as the program cell may be 3/8.

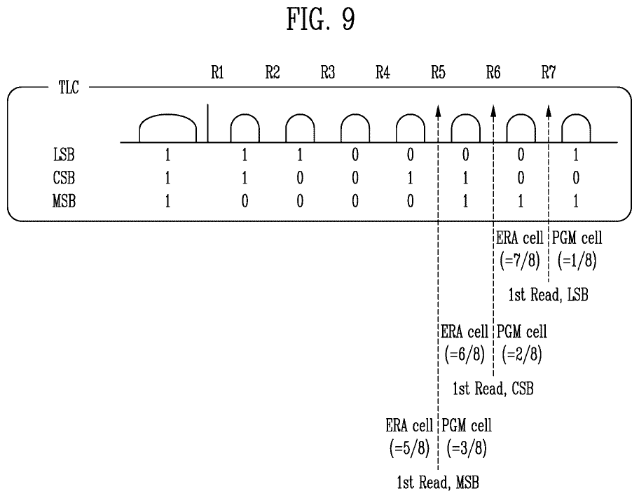

FIG. 10 is a diagram illustrating a probability that a memory cell will be read as a program cell in the second sensing operation in accordance with an embodiment of the present disclosure.

Referring to FIG. 10, in the case of the second sensing operation as a next sensing operation performed after the first sensing operation as the initial sensing operation, a bit line shielding cell exists in memory cell reading. Therefore, in the case of the second sensing operation of sensing Least Significant Bit (LSB) data stored in the memory cell according to the third read level R3, the probability that the memory cell will be read as a program cell may be 4/8. In the case of the second sensing operation of sensing Central Significant Bit (CSB) data stored in the memory cell according to the fourth read level R4, the probability that the memory cell will be read as the program cell may be 2/8. In the case of the second sensing operation of sensing Most Significant Bit (MSB) data stored in the memory cell according to the first read level R1, the probability that the memory cell will be read as the program cell may be 4/8.

FIG. 11 is a diagram illustrating setting operation on a page buffer control signal in accordance with an embodiment of the present disclosure.

Referring to FIG. 11, the setting information on the page buffer control signal may include offset voltage level of a page buffer control signal corresponding to a read voltage level of a read voltage. The setting information may include a probability that a memory cell connected to a bit line adjacent to a bit line connected to a selected memory cell will be read as a program cell by the read voltage level. The setting information may include an under drive group UD Group to which the read voltage level belongs according to the offset voltage level. The magnitude of the offset voltage level may be in inverse proportion to the probability that the memory cell will be read as the program cell.

For example, a target voltage level of the page buffer control signal may be determined based on a default voltage level and an offset voltage level of the page buffer control signal. The offset voltage level may be determined according to the probability that the memory cell connected to the bit line adjacent to the bit line will be read as the program cell by the read voltage level.

In FIG. 11, when the read level of a read voltage Vread is a seventh read level V7, the probability that the memory cell connected to the adjacent bit line will be read as the program cell by the seventh read level R7 in the sensing operation may be 1/8. The level of an offset voltage Voffset may be −0.3V. Therefore, the level of a target voltage Vtar of the page buffer control signal may be 0.9.

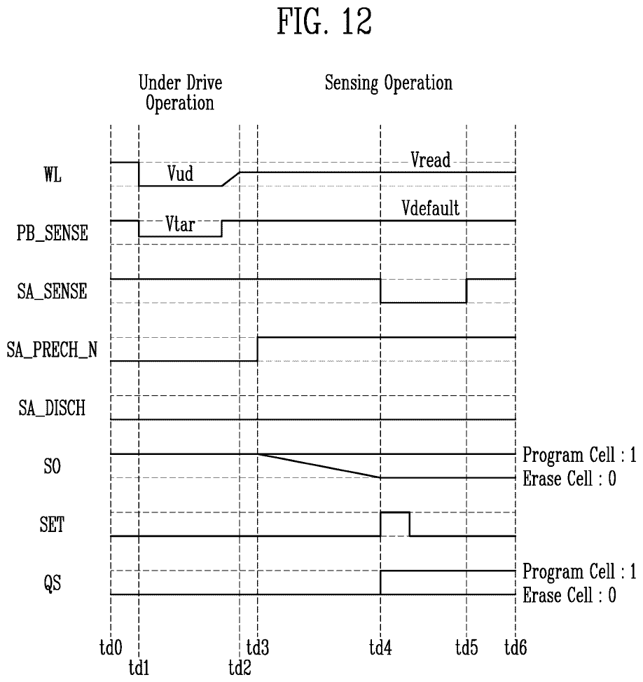

FIG. 12 is a diagram illustrating a page buffer under drive operation and a sensing operation in accordance with an embodiment of the present disclosure.

Referring to FIG. 12, a sensing operation performed from td2 (i.e., time point td2) to td6 (i.e., time point td6) may be performed like the sensing operation described with reference to FIG. 4. In another embodiment, when the sensing operation performed from td2 to td6 is a subsequent next sensing operation instead of an initial sensing operation, the sensing operation may be performed like the sensing operation described with reference to FIGS. 5A and 5B.

An under drive operation may be performed from td0 to td2 as a period before the sensing operation is performed. The under drive operation may include a word line under drive operation and a page buffer under drive operation.

The word line under drive operation may be an operation of applying, to a word line, an under drive voltage Vud having a level lower than a level of a read voltage Vread before the sensing operation.

The page buffer under drive operation may be an operation of applying a page buffer control signal having a level of a target voltage Vtar to a page buffer control switch. The page buffer under drive operation may be terminated before the word line under drive operation is terminated. The level of the target voltage Vtar may be determined based on a read voltage level of the read voltage Vread applied to a word line connected to a memory cell in the sensing operation as described with reference to FIG. 11.

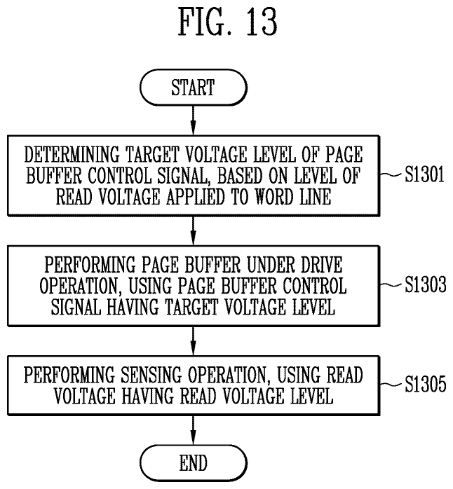

FIG. 13 is a flowchart illustrating an operation of the memory device in accordance with an embodiment of the present disclosure.

Referring to FIG. 13, in step S1301, the memory device may determine a target voltage level of a page buffer control signal, based on a level of a read voltage applied to a word line connected to a memory cell.

In step S1303, the memory device may perform a page buffer under drive operation, using a page buffer control signal having a target voltage level. The page buffer under drive operation may be an operation of applying the page buffer control signal having the target voltage level to a page buffer switch before a sensing operation.

In step S1305, the memory device may perform the sensing operation, using a read voltage having a read voltage level.

In accordance with an embodiment of the present disclosure, there can be provided a page buffer, a memory device including a page buffer, and an operating method thereof, in which a voltage level of a page buffer control signal is adjusted before a sensing operation, thereby shortening a bit line settling time and performing the sensing operation.

While the present disclosure has been shown and described with reference to certain examples of embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described examples of embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the examples of embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a memory cell array including a memory cell;
a page buffer connected to the memory cell through a bit line, the page buffer configured to perform a sensing operation of sensing program data stored in the memory cell; and
a bit line operation controller configured to control the page buffer to perform a page buffer under drive operation before the sensing operation,
wherein the page buffer includes:
a latch circuit configured to store the program data;
a sense amplifier (amp) circuit configured to perform the sensing operation; and
a page buffer control switch configured to connect the bit line to the sense amp circuit,
wherein the page buffer under drive operation is an operation of applying a page buffer control signal having a target voltage level to the page buffer control switch, and
wherein the target voltage level is determined based on a read voltage level of a read voltage applied to a word line connected to the memory cell in the sensing operation.

2. The memory device of claim 1, further comprising a page buffer control information storage configured to store setting information on the page buffer control signal.

3. The memory device of claim 2, wherein the setting information includes an offset voltage level of the page buffer control signal, which corresponds to the read voltage level.

4. The memory device of claim 3, wherein the target voltage level is determined based on a default voltage level and the offset voltage level of the page buffer control signal.

5. The memory device of claim 3, wherein the setting information includes a probability that a memory cell connected to a bit line adjacent to the bit line will be read as a program cell according to the read voltage level.

6. The memory device of claim 5, wherein a magnitude of the offset voltage level is in inverse proportion to the probability that the memory cell will be read as the program cell.

7. The memory device of claim 3, wherein the setting information includes an under drive group to which the read voltage level belongs according to the offset voltage level.

8. The memory device of claim 2, wherein the bit line operation controller determines the target voltage level, based on the setting information, and controls the page buffer to perform the page buffer under drive operation while a word line under driver operation is performed on the word line.

9. The memory device of claim 8, wherein the bit line operation controller terminates the page buffer under drive operation before a word line settling operation of setting a potential of the word line to the read voltage level is completed.

10. The memory device of claim 8, wherein the word line under drive operation is an operation of applying, to the word line, an under drive voltage having a level lower than the read voltage level before the sensing operation.

11. The memory device of claim 1, wherein the page buffer performs a next sensing operation when the read voltage level is changed after the sensing operation is performed.

12. The memory device of claim 11, wherein the page buffer disables the sense amp circuit according to a result of the sensing operation in the next sensing operation.

13. The memory device of claim 11, wherein the page buffer applies a shielding voltage to the bit line according to a result of the sensing operation in the next sensing operation.

14. A page buffer comprising:
a page buffer control switch connected between a bit line connected to a memory cell and a common sensing node, the page buffer control switch configured to be controlled according to a page buffer control signal;
first and second switches connected in series between a power node and a sensing node;
a third switch connected between the sensing node and the common sensing node, the third switch configured to be controlled according to a sense amplifier (amp) sensing signal;
fourth and fifth switches connected in series between the sensing node and a ground node; and
a latch circuit configured to store data sensed from the memory cell,
wherein the first switch and the fifth switch are controlled according to the data stored in the latch circuit,
wherein the second switch is controlled according to a sense amp precharge signal,
wherein the fourth switch is controlled according to a sense amp discharge signal,
wherein the page buffer control signal having a target voltage level is applied to the page buffer control switch before a sensing operation on the memory cell, and
wherein the target voltage level is determined according to a read voltage level of a read voltage applied to a word line connected to the memory cell in the sensing operation.

15. The page buffer of claim 14, wherein the target voltage level is determined based on a default voltage level and an offset voltage level of the page buffer control signal, and
wherein the offset voltage level is determined according to a probability that a memory cell connected to a bit line adjacent to the bit line will be read as a program cell according to the read voltage level.

16. The page buffer of claim 14, wherein the page buffer control signal maintains the target voltage level while an under drive voltage having a level lower than the read voltage level is applied to the word line, and is changed from the target voltage level to a default voltage level before a potential of the word line reaches the read voltage level.

17. The page buffer of claim 14, wherein the bit line applies a shielding voltage according to a result of the sensing operation in a next sensing operation in which the read voltage level is changed.

18. The page buffer of claim 17, wherein the sense amp discharge signal is inactivated in the sensing operation, and is activated in the next sensing operation.

19. A method of operating a memory device, the method comprising:
performing a page buffer under drive operation before a sensing operation of sensing data stored in a memory cell; and
performing the sensing operation by applying a read voltage to a word line connected to the memory cell,
wherein the performing of the page buffer under drive operation includes:
determining a target voltage level of a page buffer control signal, based on a read voltage level of the read voltage; and
applying the page buffer control signal having the target voltage level to a page buffer control switch connecting a bit line connected to the memory cell to a latch circuit storing the data.

20. The method of claim 19, wherein, in the determining of the target voltage level, the target voltage level is determined based on a default voltage level and an offset voltage level of the page buffer control signal, and
wherein the offset voltage level is determined according to a probability that a memory cell connected to a bit line adjacent to the bit line will be read as a program cell according to the read voltage level.
